(19) United States
(12) Patent Application Publication
(10) Pub. No.: US 2019/0090367 A1
(43) Pub. Date: Mar. 21, 2019

(54) ELECTRONIC DEVICE CASING AND MANUFACTURING METHOD THEREOF

(71) Applicant: Lite-On Technology Corporation, Taipei (TW)

(72) Inventors: Jun-Wen Teng, Taipei (TW); Chieh-Hung Chen, Taipei (TW)

(73) Assignee: Lite-On Technology Corporation, Taipei (TW)

(21) Appl. No.: 15/807,595

(22) Filed: Nov. 9, 2017

(30) Foreign Application Priority Data
Sep. 21, 2017 (CN) 201710857766.5

(51) Int. Cl. H05K 5/02; B29C 45/16

(52) U.S. Cl. CPC H05K 5/0217; B29L 2031/712; B29C 45/1676

(57) ABSTRACT

An electronic device casing includes a main casing and a flexible member. The main casing includes a first surface and a second surface opposite to each other, an opening passing through the first surface and the second surface, and a fixing member located near the opening and protruding from the second surface. The flexible member and the main casing are integrally formed by double injection molding. The flexible member is disposed on the second surface and covers the opening. The fixing member passes through the flexible member. A manufacturing method of electronic device casing is further provided.

### CROSS REFERENCE TO RELATED APPLICATION

This application claims the priority benefit of Chinese application serial no. 201710857766.5, filed on Sep. 21, 2017. The entirety of the above-mentioned patent application is hereby incorporated by reference herein and made a part of specification.

### BACKGROUND OF THE INVENTION

### Field of the Invention

The invention relates to a casing and a manufacturing method thereof, and in particular, to an electronic device casing and a manufacturing method thereof.

### Description of Related Art

To diversify the environments in which an electronic device can be applied, for example, by providing water-proofing and dust-proofing effects on the electronic device, it is usually required to additionally provide a flexible water-proof component on a main casing of the electronic device, and it is required to perform an additional process to assemble the water-proof component to the main casing of the electronic device. In addition to complicating the manufacturing, this additional process may easily lead to assembly errors. Moreover, since the main casing of the electronic device may need to undergo other high-temperature processes, the water-proof component assembled on the main casing of the electronic device may be easily warped or peeled off the main casing after heating, which results in loss of the water-proofing and dust-proofing effects.

### SUMMARY OF THE INVENTION

The invention provides an electronic device casing capable of decreasing assembly errors between a flexible member and a main casing and reducing a possibility of the flexible member being warped or peeled off the main casing after the electronic device casing undergoes a high-temperature process and is assembled.

The invention provides a manufacturing method of electronic device casing for manufacturing the foregoing electronic device casing.

An electronic device casing of the invention includes a main casing and a flexible member. The main casing includes a first surface and a second surface opposite to each other, an opening passing through the first surface and the second surface, and a fixing member located near the opening and protruding from the second surface. The flexible member is integrally formed with the main casing by double injection molding. The flexible member is disposed on the second surface and covers the opening, and the fixing member passes through the flexible member.

An electronic device casing of the invention includes a main casing and a flexible member. The main casing includes a first surface and a second surface opposite to each other, an opening passing through the first surface and the second surface, and a position limiting member located near the opening and protruding from the second surface. The flexible member is integrally formed with the main casing by double injection molding. The flexible member is disposed on the second surface and covers the opening, and the position limiting member covers part of an edge of the flexible member.

An electronic device casing of the invention includes a main casing and a flexible member. The main casing includes a first surface and a second surface opposite to each other, a fixing member protruding from the second surface, and a position limiting member protruding from the second surface. The flexible member is integrally formed with the main casing by double injection molding. The flexible member is disposed on the second surface, the fixing member passes through the flexible member, and the position limiting member covers part of an edge of the flexible member.

A manufacturing method of electronic device casing of the invention includes: providing a mold; and injecting a first material and a second material into the mold by double injection, and curing the first material and the second material to respectively form a main casing and a flexible member of an electronic device casing, wherein the main casing includes a first surface and a second surface opposite to each other, an opening passing through the first surface and the second surface, and a fixing member located near the opening and protruding from the second surface, wherein the flexible member is disposed on the second surface and covers the opening, and the fixing member passes through the flexible member.

In an embodiment of the invention, the first surface and the second surface are respectively an external surface and an internal surface, and the main casing further includes at least one position limiting member protruding from the second surface and covering part of an edge of the flexible member.

In an embodiment of the invention, the at least one position limiting member includes two position limiting members covering two opposite edges of the flexible member.

In an embodiment of the invention, the fixing member includes at least one column located near an edge of the flexible member.

In an embodiment of the invention, the at least one column is a plurality of columns surrounding the opening.

In an embodiment of the invention, the fixing member includes at least one wall located near an edge of the flexible member.

In an embodiment of the invention, the at least one wall is a plurality of walls discontinuously surrounding the opening.

In an embodiment of the invention, the at least one wall continuously surrounds the opening.

In an embodiment of the invention, the electronic device casing further includes a button exposed on the first surface and movably disposed on the opening. The button is connected to a portion of the flexible member corresponding to the opening.

In an embodiment of the invention, a material of the main casing includes a plastic containing an organic metal complex, and a material of the flexible member includes a rubber or a silica gel.

In light of the above, the flexible member and the main casing of the electronic device casing of the invention are manufactured together by double injection molding, such that the flexible member and the main casing are integrally formed and the issue of assembly errors can be avoided. Moreover, a contact area between the main casing and the flexible member is increased by additionally passing the fixing member protruding from the second surface through the flexible member to reduce a possibility of the flexible member being peeled off the main casing due to deformation and warpage after heating.

To provide a further understanding of the aforementioned and other features and advantages of the disclosure, exemplary embodiments, together with the reference drawings, are described in detail below.

### BRIEF DESCRIPTION OF THE DRAWINGS

FIG. 1 is a schematic diagram illustrating an electronic device casing according to an embodiment of the invention.

FIG. 2 is a schematic diagram illustrating FIG. 1 from another angle of view.

FIG. 3 is a cross-sectional schematic diagram along line A-A of FIG. 2.

FIG. 4 is a schematic diagram illustrating a partial front view of FIG. 2.

FIG. 5 to FIG. 8 are respectively partial schematic diagrams illustrating multiple types of electronic device casings according to other embodiments of the invention.

FIG. 9 is a partial schematic diagram illustrating an electronic device casing according to another embodiment of the invention.

FIG. 10 is a partial schematic diagram illustrating an electronic device casing according to another embodiment of the invention.

### DESCRIPTION OF THE EMBODIMENTS

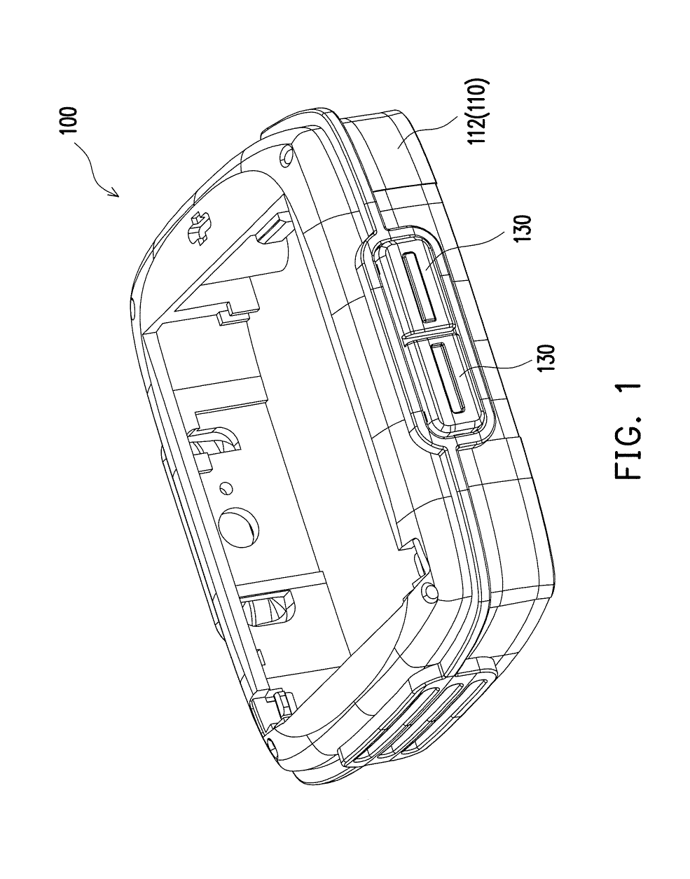

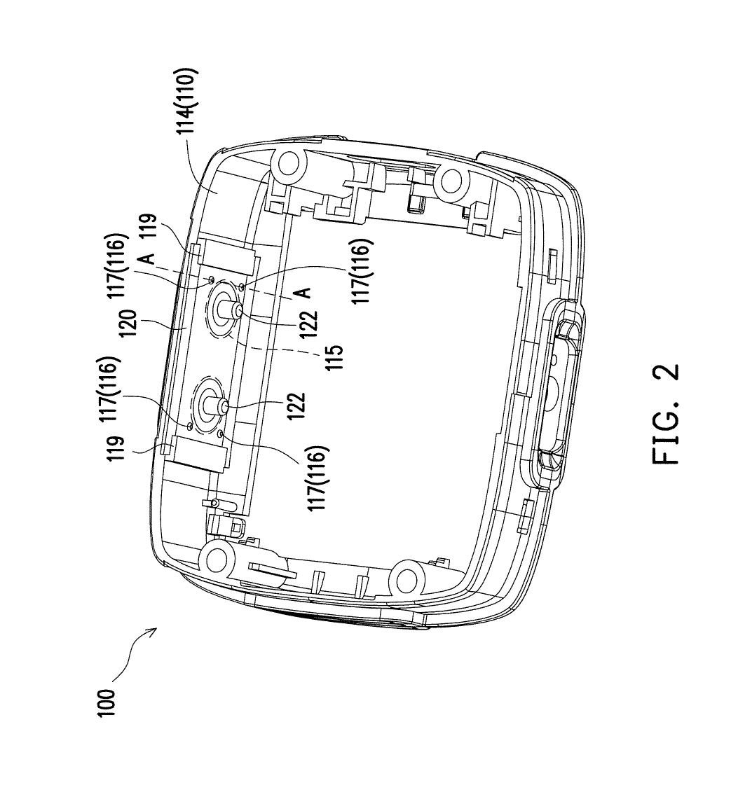

FIG. 1 is a schematic diagram illustrating an electronic device casing according to an embodiment of the invention. FIG. 2 is a schematic diagram illustrating FIG. 1 from another angle of view. Referring to FIG. 1 to FIG. 2, in the present embodiment, an electronic device casing 100 is, for example, a wearable electronic device casing, such as an electronic device casing in a watch body form of a watch. In the figures, to clearly illustrate the interior of the electronic device casing 100, a circuit module (not illustrated) and other internal structures placed in the electronic device casing 100 are intentionally concealed. Of course, the type of application of the electronic device casing 100 is not limited hereto. In other embodiments, the electronic device casing 100 may also be an electronic device casing in a bracelet form, or an electronic device casing in various forms including a necklace, glasses, etc.

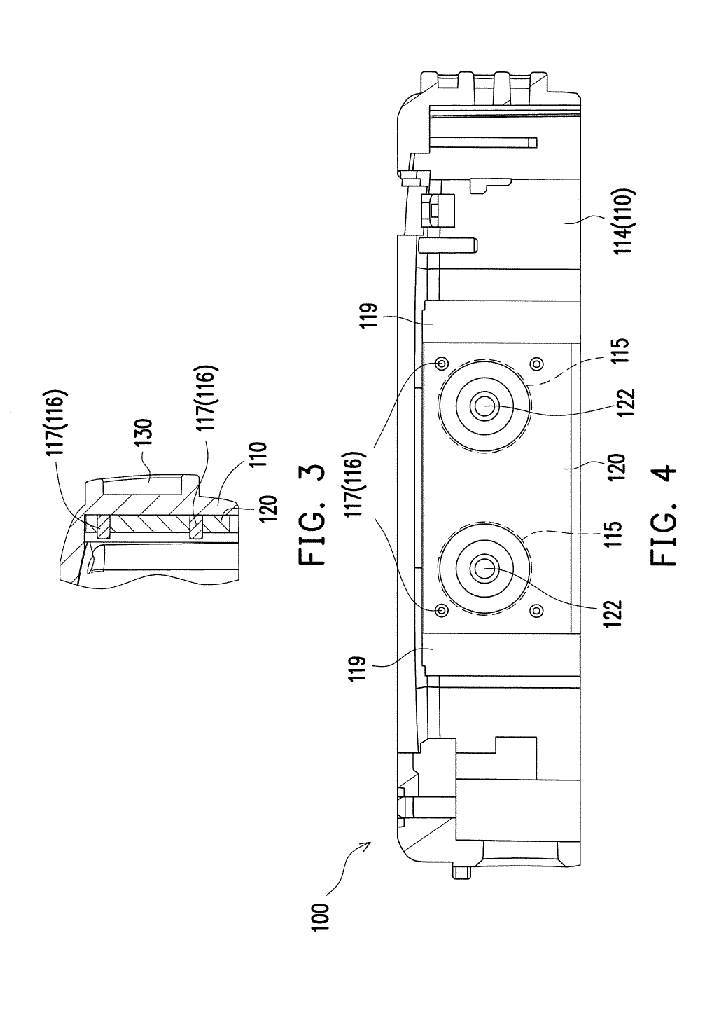

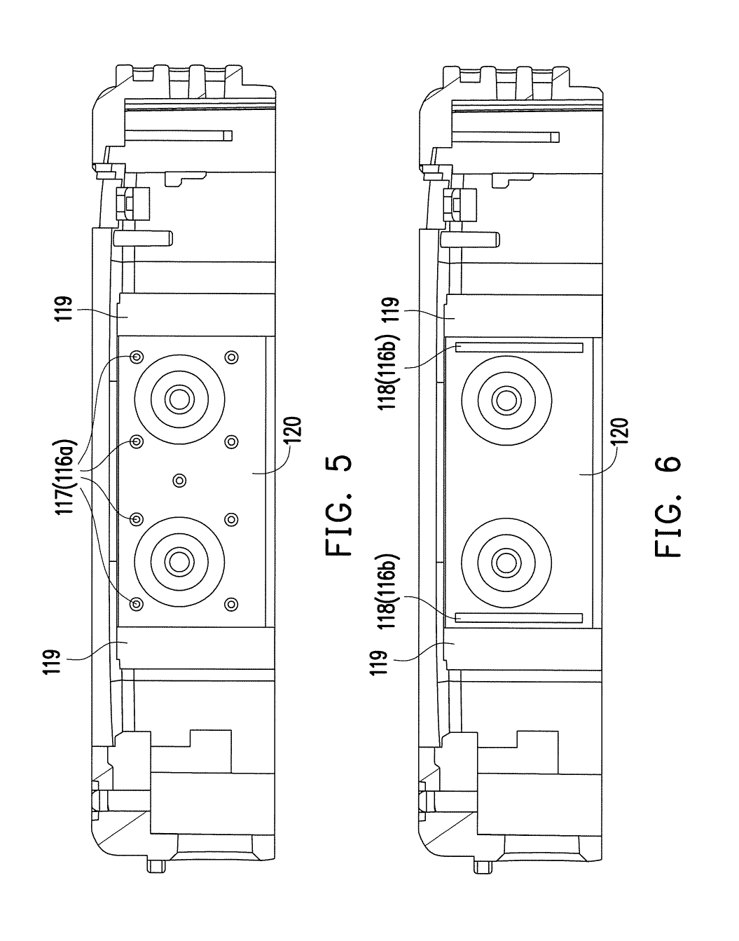

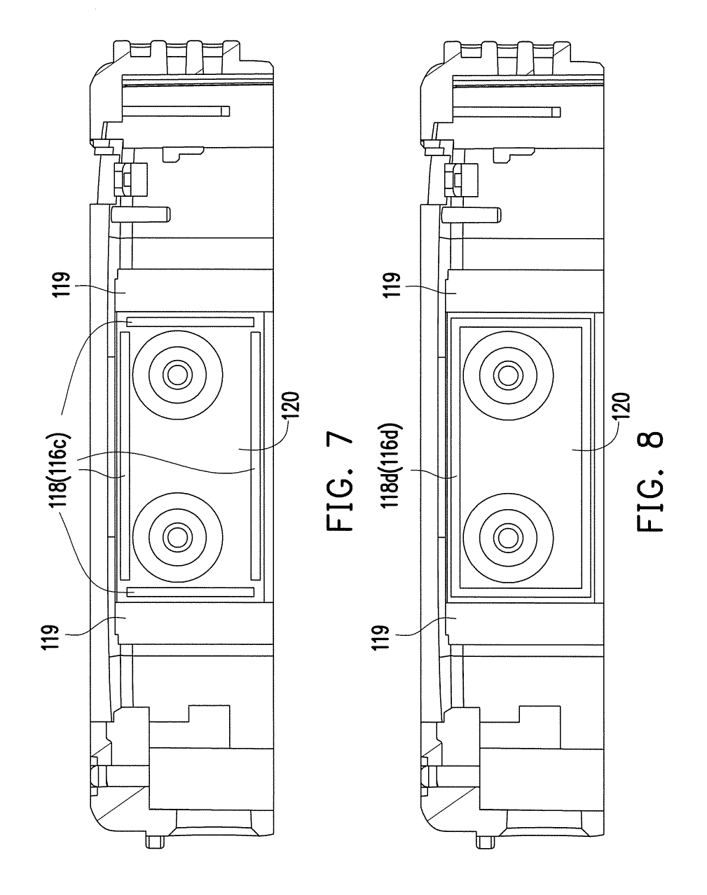

FIG. 3 is a cross-sectional schematic diagram along line A-A of FIG. 2. FIG. 4 is a schematic diagram illustrating a partial front view of FIG. 2. Referring to FIG. 1 to FIG. 4 at the same time, the electronic device casing 100 of the present embodiment includes a main casing 110, a flexible member 120 (labeled in FIG. 2), and a button 130 (labeled in FIG. 1). In the present embodiment, the main casing 110 includes a first surface 112 (labeled in FIG. 1) and a second surface 114 (labeled in FIG. 2) opposite to each other, and an opening 115 (labeled in FIG. 2; the opening 115 of the main casing 110 is rendered in broken lines because it is covered by the flexible member 120) passing through the first surface 112 and the second surface 114. In the present embodiment, the first surface 112 is an external surface and the second surface 114 is an internal surface, but the configurational relationship between the first surface 112 and the second surface 114 is not limited hereto.

In the present embodiment, the flexible member 120 and the main casing 110 are integrally formed by double injection molding. Since the flexible member 120 and the main casing 110 are integrally formed, the issue of assembly errors between the two may be avoided. Moreover, in the present embodiment, the flexible member 120 is disposed on a position on the second surface 114 of the main casing 110 corresponding to the opening 115, such that the flexible member 120 covers the opening 115 and the flexible member 120 is sealed on a portion of the second surface 114 of the main casing 110 surrounding the opening 115. In other words, external liquid cannot enter the inside of the main casing 110 through the opening 115 and a gap between the button 130 and the main casing 110. Therefore, the electronic device casing 100 of the present embodiment achieves water-proofing and dust-proofing effects at the portion corresponding to the button 130.

In the present embodiment, the button 130 is exposed on the first surface 112 (FIG. 1) and is movably disposed at a position on the main casing 110 corresponding to the opening 115. Therefore, when the button 130 is pressed, the button 130 pushes the portion of the flexible member 120 corresponding to the opening 115, such that the portion of the flexible member 120 corresponding to the opening 115 is correspondingly deformed, and a propping portion 122 (FIG. 2) of the flexible member 120 is moved inward and further triggers the circuit module (not illustrated) located in the electronic device casing 100. In different embodiments, the button 130 may include a portion passing through the opening 115 of the main casing 110, and this portion of the button 130 is connected to the portion of the flexible member 120 corresponding to the opening 115. Alternatively, the flexible member 120 may include a portion passing through the opening 115 of the main casing 110, and this portion of the flexible member 120 is connected to the button 130. The configurations above can equally achieve the function of pressing the button 130 to cause the portion of the flexible member 120 corresponding to the opening 115 to be moved together and further cause the propping portion 122 of the flexible member 120 to trigger the circuit module (not illustrated).

In the present embodiment, since a number of the buttons 130 (as shown in FIG. 1) is two, a number of the openings 115 of the main casing 110 is correspondingly two (as shown in FIG. 2). Of course, in other embodiments, it is also possible that the number of the openings 115 of the main casing 110 does not correspond to the number of the buttons 130, and the number and the form of the buttons 130 are not limited to the illustration in the figures.

It shall be mentioned that, as shown in FIG. 2 to FIG. 4, in the present embodiment, the main casing 110 further includes a fixing member 116 located near the opening 115, protruding from the second surface 114, and passing through the flexible member 120. Accordingly, through the fixing member 116, a contact area between the main casing 110 and the portion of the flexible member 120 near the opening 115 is increased, which effectively increases adhesion between the main casing 110 and the portion of the flexible member 120 and reduces a possibility of the flexible member 120 being peeled off the main casing 110.

More specifically, the fixing member 116 of the main casing 110 includes at least one column 117 located near an edge of the flexible member 120. As shown in FIG. 4, in the present embodiment, the at least one column 117 includes multiple columns 117, and the columns 117 are located on outer peripheries of the two openings 115 and surround the openings 115. In the present embodiment, the column 117 is disposed at a position near the edge of the flexible member 120 to increase a contact area between a portion of the edge of the flexible member 120 and the main casing 110. Meanwhile, the configuration of the column 117 near the opening 115 partially strengthens tightness of adhesion of the flexible member 120 to the second surface 114 and further reduces a possibility of the flexible member 120 being peeled off the main casing 110 due to warpage of the edge of the flexible member 120. Of course, in other embodiments, the configurational relationship between the fixing member 116 and the opening 115 and the form of the fixing member 116 are not limited hereto.

Moreover, in the present embodiment, the main casing 110 further includes at least one position limiting member 119 protruding from the second surface 114 and covering part of the edge of the flexible member 120. In the present embodiment, each position limiting member 119 protrudes from the second surface 114 in a form of a bent arm, but the shape of the position limiting member 119 is not limited hereto. Specifically, in the present embodiment, the at least one position limiting member 119 includes two position limiting members 119 covering two opposite edges of the flexible member 120. In other words, the electronic device casing 100 of the present embodiment increases the contact area between the main casing 110 and the flexible member 120 through the fixing member 116 passing through the flexible member 120, and reduces a possibility of the flexible member 120 moving relatively to the main casing 110 in upward-downward and leftward-rightward directions of FIG. 4. Moreover, the electronic device casing 100 of the present embodiment also covers the edge portions of the flexible member 120 through the two position limiting members 119 to prevent the edges of the flexible member 120 from moving relatively to the main casing 110 in a direction passing outward from the drawing surface of FIG. 4, such that the edge portions of the flexible member 120 covered by the two position limiting members 119 are limited by the two position limiting members 119 and are not warped. It shall be mentioned that, in the present embodiment, as the electronic device casing 100 is, as an example, the electronic device casing 100 in the watch body form of a watch, such wearable electronic device may be provided with an antenna (not illustrated). Here, one of a number of methods of manufacturing the electronic device casing 100 of the present embodiment is provided. First, a mold for forming the electronic device casing 100 is provided. Then, a first material and a second material are injected into the mold by double injection, and the first material and the second material are cured to respectively form the main casing 110 and the flexible member 120 of the electronic device casing 100.

In the present embodiment, the first material (i.e., the material of the main casing 110) includes a plastic containing an organic metal complex. For example, the first material includes polycarbonate (PC) or a polycarbonate/acrylonitrile-butadiene-styrene (PC/ABS) copolymer containing an organic metal complex. Moreover, the second material (i.e., the material of the flexible member 120) includes a rubber or a silica gel, such as thermoplastic polyurethane (TPU). Of course, the materials of the main casing 110 and the flexible member 120 are not limited hereto. In the present embodiment, the main casing 110 formed of the first material is, for example, a hard casing but is not limited hereto. Moreover, in the present embodiment, the material of the main casing 110 may be identical to the material of the fixing member 116 and/or the position limiting member 119. In other embodiments, the material of the main casing 110 may be different from the material of the fixing member 116 and/or the position limiting member 119.

If an antenna is to be formed on the electronic device casing 100, since the material of the main casing 110 includes a plastic containing an organic metal complex, a manufacturer may form the antenna on the electronic device casing 100 through the technique of laser-direct-structuring (LDS). Specifically, a laser light is irradiated on a specific portion on the main casing 110 such that the laser light activates the metal material doped in the main casing 110. The metal exposed after activation by the laser light provides a seed layer for a subsequent electroplating process. In the subsequent electroplating process, a metal layer (surface metallization) is grown in the region of the main casing 110 activated by the laser light to form the antenna on the main casing 110.

It shall be noted that since a temperature of the electroplating process is about 70 to 80 degrees, in the electroplating process, an overall temperature of the electronic device casing 100 is increased altogether, and the electronic device casing 100 of the present embodiment increases the contact area between the main casing 110 and the flexible member 120 through the fixing member 116 passing through the flexible member 120. In some embodiments, the electronic device casing 100 further covers the flexible member 120 by two position limiting members 119 to reduce a possibility of warpage of the edge portions of the flexible member 120 due to heating.

It shall be mentioned that, after manufacturing of the electronic device casing 100 is completed, different heating processes, such as a baking process, a laser heating, or an infrared heating, may be applied according to different needs. The heating process is not limited to the electroplating process described above. In the electronic device casing 100 of the present embodiment, the designs of the fixing member 116 and the position limiting member 119 effectively enable the flexible member 120 to maintain its position relative to the main casing 110 without deformation when undergoing the heating process. Of course, it is also possible that the electronic device casing 100 does not need to undergo the heating process. Moreover, the method of forming the antenna on the main casing 110 is not limited to the foregoing method, either. In other embodiments, the antenna may be formed on the main casing 110 through methods including adhesion and spray coating. Therefore, in other embodiments, it is also possible that the material of the main casing 110 is not doped with metal.

The description below provides the fixing member in other forms according to other embodiments. FIG. 5 to FIG. 8 are respectively partial schematic diagrams illustrating multiple types of electronic device casings according to other embodiments of the invention. Referring to FIG. 5 first, a main difference between the embodiment of FIG. 5 and the embodiment of FIG. 4 lies in the distribution forms of the fixing members 116, 116a. In FIG. 4, the number of the columns 117 is four, and the columns 117 are located at four edge corners of the flexible member 120. In FIG. 5, it is noted that the number of the columns 117 is nine, and the columns 117 are located at a center of the flexible member 120 in addition to the edges of the flexible member 120. Of course, in other embodiments, the number of the columns 117 and their positions relative to the flexible member 120 are not limited hereto.

Referring to FIG. 6, a main difference between the embodiment of FIG. 6 and the embodiment of FIG. 4 lies in the forms of the fixing members 116, 116b. In FIG. 4, the type of the fixing member 116 is the column 117. In the present embodiment, the fixing member 116b includes at least one wall 118 located near the edge of the flexible member 120. More specifically, the at least one wall 118 includes two walls 118 disposed on two opposite edges of the flexible member 120. The fixing member 116b present in the form of the wall 118 similarly increases the contact area with the flexible member 120, which increases adhesion between the main casing 110 and the portion of the flexible member 120 and reduces a possibility of deformation of the flexible member 120.

Referring to FIG. 7, a main difference between the embodiment of FIG. 7 and the embodiment of FIG. 6 lies in the configurational positions of the fixing members 116b, 116c. In the present embodiment, the number of the walls 118 is four, and the walls 118 are disposed on the four edges of the flexible member 120 to more effectively reduce the possibility of deformation of the flexible member 120.

Referring to FIG. 8, a main difference between the embodiment of FIG. 8 and the embodiment of FIG. 7 lies in that, in FIG. 7, the walls 118 discontinuously surround the openings 115. In the present embodiment, a fixing member 116d is continuously disposed on the four edges of the flexible member 120 as a single wall 118d and continuously surrounds the openings 115.

Of course, the forms of the fixing members 116, 116a, 116b, 116c, 116d are not limited to the descriptions above. In other embodiments, the fixing members 116, 116a, 116b, 116c, 116d may also be a combination of the column 116 and the walls 118, 118d, or a combination of other three-dimensional shapes. Alternatively, in other embodiments, the column may have a variation in a radial dimension along a direction protruding from the second surface 114, for example, in an inverted cone shape (wide at the top and narrow at the bottom), or the column may be in a stepped tower shape or Christmas tree shape having a discontinuous variation in size along the direction protruding from the second surface 114. Since the radial dimension of at least a portion of the column in the direction away from the second surface 114 is greater than the radial dimension in the direction close to the second surface 114, the flexible member 120 is even more unlikely to fall off the main casing 110, and excellent adhesion is provided.

FIG. 9 is a partial schematic diagram illustrating an electronic device casing according to another embodiment of the invention. Referring to FIG. 9, a main difference between an electronic device casing 100e of FIG. 9 and the electronic device casing 100 of FIG. 4 lies in that, in FIG. 4, the main casing 110 of the electronic device casing 110 includes the fixing member 116 passing through the flexible member 120 and the position limiting member 119 covering the edge portions of the flexible member 120. In the present embodiment, a main casing 110e of the electronic device casing 100e includes the position limiting member 119 covering the edge portions of the flexible member 120 and does not include the fixing member 116 in FIG. 4.

In the electronic device casing 100e of the present embodiment, the two position limiting members 119 prevent the edges of the flexible member 120 from moving relatively to the main casing 110 in a direction passing outward from the drawing surface of FIG. 9, such that the edge portions of the flexible member 120 covered by the two position limiting members 119 are limited by the two position limiting members 119 and are not warped.

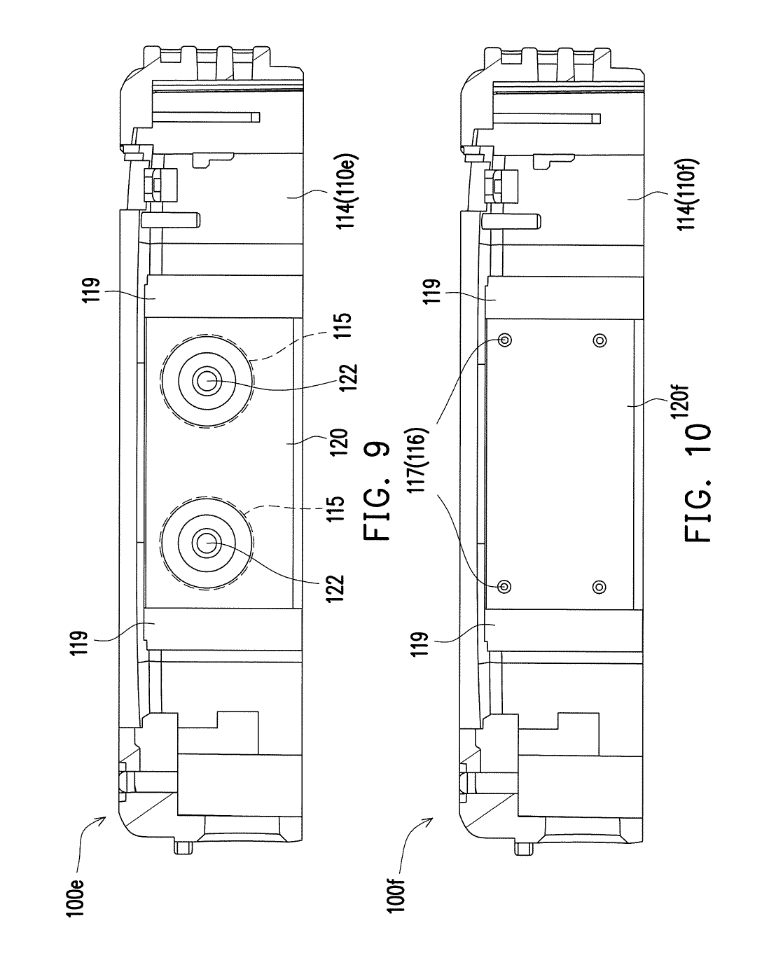

FIG. 10 is a partial schematic diagram illustrating an electronic device casing according to another embodiment of the invention. Referring to FIG. 10, a main difference between an electronic device casing 100f of FIG. 10 and the electronic device casing 100 of FIG. 4 lies in that, in FIG. 4, the main casing 110 includes the opening 115 (rendered in broken lines) passing through, the flexible member 120 covers the opening 115, and the flexible member 120 includes the propping portion 122 at the position corresponding to the opening 115. In FIG. 10, a main casing 110f does not include the opening 115 in FIG. 4, and a flexible member 120f does not include the propping portion 122 of FIG. 4. In other words, the main casing 110f is disposed with a flexible member 120f next to a desired position, the main casing 110f passes through the flexible member 120f through the fixing member 116, and the position limiting members 119 cover the edge portions of the flexible member 120f to fix the flexible member 120f.

In summary of the above, the flexible member and the main casing of the electronic device casing of the invention are manufactured together by double injection molding, such that the flexible member and the main casing are integrally formed and the issue of assembly errors can be avoided. Moreover, the contact area between the main casing and the flexible member is increased by additionally passing the fixing member protruding from the second surface through the flexible member to reduce the possibility of the flexible member being peeled off the main casing due to deformation and warpage after heating. Alternatively, the main casing of the electronic device casing includes the position limiting member covering the edge portions of the flexible member, and the edge portions of the flexible member covered by the position limiting member are limited by the position limiting member and are not warped.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

What is claimed is:

1. An electronic device casing comprising:
a main casing comprising a first surface and a second surface opposite to each other, an opening passing through the first surface and the second surface, and a fixing member located near the opening and protruding from the second surface; and
a flexible member integrally formed with the main casing by double injection molding, wherein the flexible member is disposed on the second surface and covers the opening, and the fixing member passes through the flexible member.

2. The electronic device casing according to claim 1, wherein the first surface and the second surface are respectively an external surface and an internal surface, and the main casing further comprises at least one position limiting member protruding from the second surface and covering part of an edge of the flexible member.

3. The electronic device casing according to claim 2, wherein the at least one position limiting member comprises two position limiting members covering two opposite edges of the flexible member.

4. The electronic device casing according to claim 1, wherein the fixing member comprises at least one column located near an edge of the flexible member.

5. The electronic device casing according to claim 4, wherein the at least one column comprises a plurality of columns surrounding the opening.

6. The electronic device casing according to claim 1, wherein the fixing member comprises at least one wall located near an edge of the flexible member.

7. The electronic device casing according to claim 6, wherein the at least one wall comprises a plurality of walls discontinuously surrounding the opening.

8. The electronic device casing according to claim 6, wherein the at least one wall continuously surrounds the opening.

9. The electronic device casing according to claim 1, wherein a material of the main casing comprises a plastic containing an organic metal complex, and a material of the flexible member comprises a rubber or a silica gel.

10. An electronic device casing comprising:
a main casing comprising a first surface and a second surface opposite to each other, a fixing member protruding from the second surface, and a position limiting member protruding from the second surface; and
a flexible member integrally formed with the main casing by double injection molding, wherein the flexible member is disposed on the second surface, the fixing member passes through the flexible member, and the position limiting member covers part of an edge of the flexible member.

11. A manufacturing method of electronic device casing, comprising:
providing a mold; and
injecting a first material and a second material into the mold by double injection, and curing the first material and the second material to respectively form a main casing and a flexible member of an electronic device casing, wherein the main casing comprises a first surface and a second surface opposite to each other, an opening passing through the first surface and the second surface, and a fixing member located near the opening and protruding from the second surface, wherein the flexible member is disposed on the second surface and covers the opening, and the fixing member passes through the flexible member.

12. The manufacturing method of electronic device casing according to claim 11, wherein the first surface and the second surface are respectively an external surface and an internal surface, and the main casing further comprises at least one position limiting member protruding from the second surface and covering part of an edge of the flexible member.

13. The manufacturing method of electronic device casing according to claim 12, wherein the at least one position limiting member comprises two position limiting members covering two opposite edges of the flexible member.

14. The manufacturing method of electronic device casing according to claim 11, wherein the fixing member comprises at least one column located near an edge of the flexible member.

15. The manufacturing method of electronic device casing according to claim 14, wherein the at least one column comprises a plurality of columns surrounding the opening.

16. The manufacturing method of electronic device casing according to claim 11, wherein the fixing member comprises at least one wall located near an edge of the flexible member.

17. The manufacturing method of electronic device casing according to claim 16, wherein the at least one wall comprises a plurality of walls discontinuously surrounding the opening.

18. The manufacturing method of electronic device casing according to claim 16, wherein the at least one wall continuously surrounds the opening.

19. The manufacturing method of electronic device casing according to claim 11, wherein the first material comprises a plastic containing an organic metal complex, and the second material comprises a rubber or a silica gel.
